(19) United States
(12) Patent Application Publication
(10) Pub. No.: US 2026/0247901 A1
(43) Pub. Date: Aug. 20, 2026

(54) SUBSTRATE PROCESSING APPARATUS

(71) Applicant: SHIBAURA MECHATRONICS CORPORATION, Kanagawa (JP)

(72) Inventors: Kengo KAMEI, Kanagawa (JP); Jun MATSUSHITA, Kanagawa (JP); Rie TESHIMA, Kanagawa (JP); Hikaru HOSHINO, Kanagawa (JP)

(21) Appl. No.: 19/538,453

(22) Filed: Feb. 12, 2026

(30) Foreign Application Priority Data
Feb. 14, 2025 (JP) 2025-022298

(51) Int. Cl. H10P 72/00

(52) U.S. Cl. CPC H10P 72/0424

(57) ABSTRACT

According to one embodiment, a substrate processing apparatus includes a rotary table having an opposing surface that faces a substrate, held by a holding member, with a gap therebetween and that has a diameter larger than that of the substrate, the rotary table being configured to rotate the substrate held by the holding member, a processing liquid supply configured to supply a processing liquid to a surface of the rotating substrate opposite to the opposing surface, and a heating unit configured to emit heating light from above the surface of the substrate to which the processing liquid is supplied, and the opposing surface has a light absorption rate of 90% or higher in at least a region that does not overlap the substrate in a plan view.

### CROSS REFERENCES TO RELATED APPLICATIONS

This application is based on and claims priority from Japanese Patent Application No. 2025-022298, filed on February 14, 2025, with the Japan Patent Office, the disclosure of which is incorporated herein in its entirety by reference.

### TECHNICAL FIELD

The present disclosure relates to a substrate processing apparatus.

### BACKGROUND

A single-wafer-type substrate processing apparatus is known in which an outer peripheral edge of a substrate such as a semiconductor wafer is held by a holder, and a processing liquid is supplied to the substrate while the substrate held by the holder is rotated by a rotary table, thereby performing an etching processing, a resist removal processing, and others. In such a substrate processing apparatus, the processing efficiency is improved by heating the substrate being processed or the processing liquid on the substrate to increase the temperature of the processing liquid. See, for example, Japanese Patent Laid-Open Publication No. 2015-211201.

### SUMMARY

As an example of a heating method in a substrate processing apparatus, there is heating by light irradiation. For example, there is a substrate processing apparatus in which a light source that emits heating light is disposed to face a substrate held by a rotary table. Since the substrate or a processing liquid on the substrate is heated by the light emitted from the light source, the processing efficiency may be improved.

In the substrate processing apparatus employing the light-based heating method, a part of the light emitted from the light source is directed outward beyond the substrate and is incident on a structure around the substrate. Then, the light is reflected from the structure around the substrate, and the reflected light is incident on the substrate. For example, the rotary table, which is the structure around the substrate, reflects the light from the light source since an outer peripheral region thereof is not blocked by the substrate. Thus, the substrate or the processing liquid on the substrate is heated not only by the light from the light source but also by the reflected light from the structure around the substrate.

However, the reflected light is blocked in a portion where a holding member for holding an outer peripheral edge of the substrate is provided. Thus, in the outer peripheral region of the substrate, there arise a region that is heated by the reflected light and a region that is not heated by the reflected light. That is, the vicinity of the holding member is not heated by the reflected light and therefore has a lower temperature than other portions, which causes a degradation in the uniformity of the processing rate (e.g., the processing amount per unit time) in the circumferential direction in the outer peripheral region of the substrate.

Embodiments of the present disclosure have been proposed to address the above-described issue, and an object thereof is to provide a substrate processing apparatus capable of improving the temperature uniformity in the circumferential direction of a substrate.

A substrate processing apparatus according to an embodiment includes a rotary table having an opposing substrate that faces a substrate, held at an outer peripheral edge thereof by a holding member, with a gap therebetween and that has a diameter larger than that of the substrate, the rotary table being configured to rotate the substrate held by the holding member, a processing liquid supply configured to supply a processing liquid to a surface of the rotating substrate opposite to the opposing surface, and a heating unit configured to emit heating light from above the surface of the substrate to which the processing liquid is supplied, wherein the opposing surface has a light absorption rate of 90% or higher in at least a region that does not overlap the substrate in a plan view.

Further, a substrate processing apparatus according to an embodiment includes a rotary holder configured to rotate a substrate held by a holding member, a processing liquid supply configured to supply a processing liquid to an upper surface of the rotating substrate, a heating unit configured to emit heating light from above the upper surface of the substrate, and a cup configured to cover an outer periphery of the rotating substrate with a gap from the substrate, wherein at least an inner wall of the cup has a light absorption rate of 90 % or higher.

According to the embodiments of the present disclosure, it is possible to improve the temperature uniformity in the circumferential direction of a substrate.

The foregoing summary is illustrative only and is not intended to be in any way restricting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a partial axial cross-sectional view illustrating a substrate processing apparatus according to a first embodiment during supply of a processing liquid.

FIG. 2 is a partial axial cross-sectional view illustrating the substrate processing apparatus of FIG. 1 during supply of a rinse liquid.

FIG. 3 is a partial axial cross-sectional view illustrating the substrate processing apparatus of FIG. 1 during loading and unloading of a substrate.

FIG. 4A is a plan view illustrating an open position of a holding member in a rotary table, and FIG. 4B is a plan view illustrating a closed position of the holding member.

FIG. 5 is a flowchart illustrating a processing sequence according to an embodiment.

FIG. 6 is a partial axial cross-sectional view illustrating a substrate processing apparatus according to a second embodiment during supply of a processing liquid.

FIG. 7 is a partial axial cross-sectional view illustrating a substrate processing apparatus according to a third embodiment during supply of a processing liquid.

FIG. 8A is a plan view illustrating a modification in which a ring-shaped region of the rotary table that does not overlap the substrate is colored black, and FIG. 8B is a plan view illustrating a modification in which a ring-shaped region located further inward than that illustrated in FIG. 8A is also colored black.

FIG. 9 is a table illustrating the optical characteristics of general PTFE (white) and conductive PTFE (black).

FIG. 10 is a graph illustrating differences in etching amount at circumferential positions when the rotary table is made of white PTFE.

FIG. 11 is a graph illustrating differences in etching amount at circumferential positions when the rotary table is made of black conductive PTFE.

### DESCRIPTION OF EMBODIMENTS

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, the embodiments of the present disclosure will be described with reference to the drawings.

### Overview

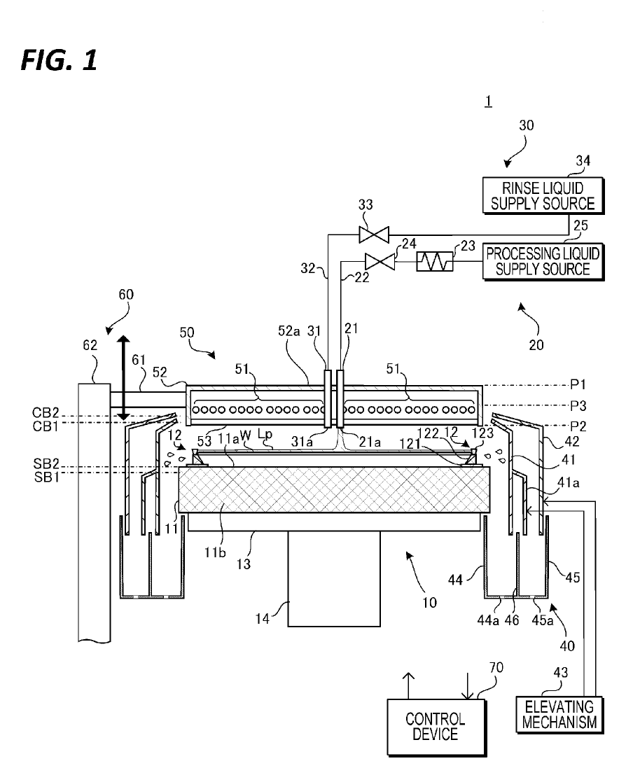

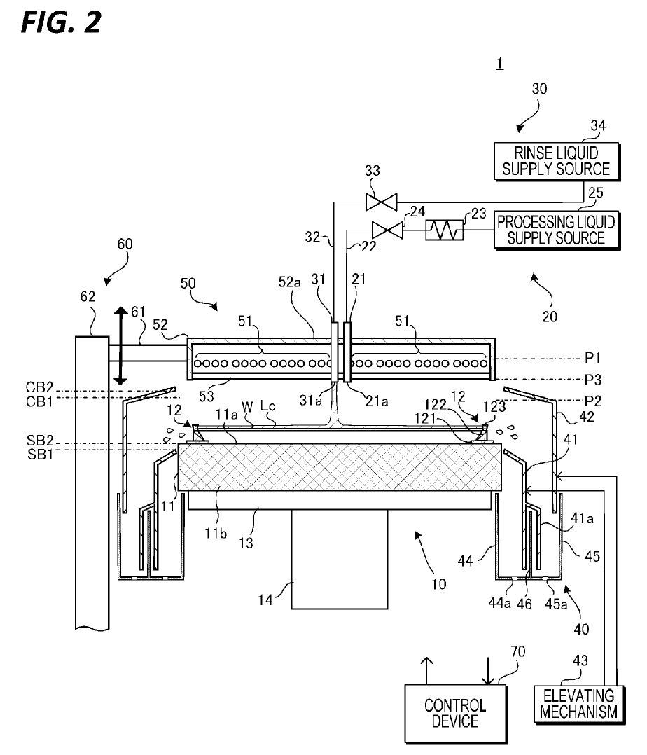

As illustrated in FIG. 1, a substrate processing apparatus 1 according to an embodiment processes a substrate W by supplying a processing liquid Lp from a processing liquid supply unit 20 to the substrate W while rotating the substrate W which is held by a rotary holder 10. The substrate processing apparatus 1 is a single-wafer-type apparatus that performs an etching processing by supplying the processing liquid Lp having an etching capability to the substrate W. In addition, as illustrated in FIG. 2, the substrate processing apparatus 1 also performs a rinse processing by supplying a rinse liquid Lc from a rinse liquid supply unit 30 to the substrate W before and after the supply of the processing liquid Lp.

The substrate processing apparatus 1 includes a heating unit 50 that heats the substrate W by light irradiation. The heating unit 50 includes a light source that emits light having a wavelength for heating the substrate W, thereby heating the substrate W itself. That is, a target heated by the heating unit 50 is the substrate W.

The substrate W, which is a processing target, is, for example, a disk-shaped silicon wafer (hereinafter, referred to as an Si substrate) having a silicon nitride film and a silicon oxide film formed on a surface thereof. The processing liquid Lp is, for example, an aqueous solution containing phosphoric acid (hereinafter, referred to as a phosphoric acid solution). The concentration of phosphoric acid in the processing liquid Lp is, for example, 85 wt% to 94 wt%. The rinse liquid Lc is, for example, pure water (H₂O).

### First Embodiment

First, the substrate processing apparatus 1 according to a first embodiment will be described.

### Configuration

The substrate processing apparatus 1 according to the first embodiment includes the rotary holding unit 10, the processing liquid supply unit 20, the rinse liquid supply unit 30, a collecting unit 40, the heating unit 50, an elevating mechanism 60, and a control device 70, as illustrated in FIG. 1.

### Rotary Holding Unit

The rotary holding unit 10 holds the substrate W by a holding member 12 to be described herein later, and rotates the held substrate W. The rotary holding unit 10 includes a rotary table 11, the holding member 12, an accommodation unit 13, and a driving unit 14.

### Rotary Table

The rotary table 11 has an opposing surface 11a that faces the substrate W held by the holding member 12 with a gap therebetween. The rotary table 11 is a cylindrical member having an upper end closed by the circular opposing surface 11a. The opposing surface 11a has a diameter larger than that of the substrate W.

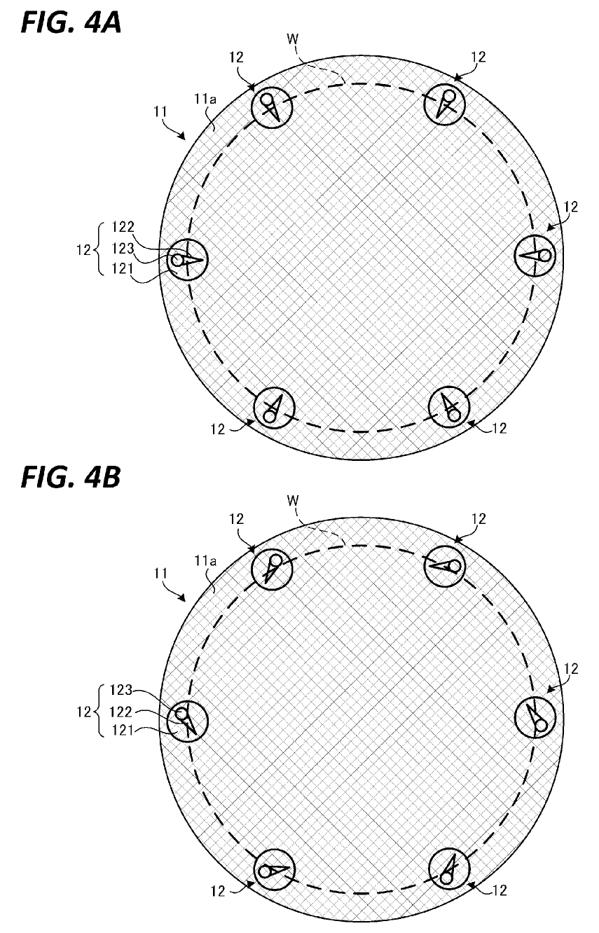

The opposing surface 11a has a high absorption rate for light (e.g., electromagnetic waves). A high light absorption rate means a light absorption rate of 90 % or higher. The light referred to here is light emitted from the heating unit 50 to be described herein later. It is sufficient that at least a region of the opposing surface 11a that does not overlap the substrate W in a plan view has a light absorption rate of 90 % or higher. However, in the present embodiment, as illustrated in FIGS. 4A and 4B, the entirety of the opposing surface 11a has a light absorption rate of 90 % or higher. In FIGS. 1 to 4A and 4B, the component having a light absorption rate of 90 % or higher is indicated by cross hatching.

The opposing surface 11a has the aforementioned light absorption rate by being made of a black material. For example, the light absorption rate is set to 90 % or higher by forming the opposing surface 11a in black using a material containing carbon. More specifically, conductive polytetrafluoroethylene (PTFE) containing carbon is used in the opposing surface 11a. Alternatively, a black material may be applied to the opposing surface 11a.

In addition, in the present embodiment, as illustrated in FIG. 1, not only the opposing surface 11a but also a side surface 11b of the rotary table 11 have a light absorption rate of 90 % or higher. To this end, both the opposing surface 11a and the side surface 11b may be configured to be black as described above.

### Holding Member

The holding member 12 is a member that holds an outer peripheral edge of the substrate W such that the opposing surface 11a faces the substrate W with a gap therebetween. As illustrated in FIG. 1, 4A, and 4B, a plurality of holding members 12 protrude from the rotary table 11, and are provided at equal intervals along positions corresponding to the outer peripheral edge of the substrate W. The holding members 12 are provided to be movable, by an opening/closing mechanism (not illustrated), between a closed position, at which the holding members 12 come into contact the outer peripheral edge of the substrate W to hold the substrate W, and an open position, at which the holding members 12 move away from the outer peripheral edge of the substrate W to release the substrate W.

The holding members 12 have a light absorption rate of 90% or higher, similarly to the opposing surface 11a. In the present embodiment, the entirety of the holding members 12 have a light absorption rate of 90 % or higher. The light absorption rate is set to 90 % or higher by forming the holding members 12 in black using a material containing carbon. For example, conductive polytetrafluoroethylene (PTFE) containing carbon is used in the holding members 12.

Each holding member 12 includes a base 121, a guide 122, and a pin 123. All of the base 121, the guide 122, and the pin 123 have a light absorption rate of 90 % or higher.

The base 121 is a cylindrical member that is rotatable about an axis parallel to the axis of the rotary table 11. Three or more bases 121 are arranged along a circle centered on the axis of the rotary table 11. This circle corresponds to the outer periphery of the substrate W positioned with the center aligned with the axis. In the present embodiment, six bases 121 are arranged at equal intervals in the circumferential direction, as illustrated in FIGS. 4A and 4B. An upper surface of each base 121 is exposed from the rotary table 11. The bases 121 are provided respectively to be synchronously rotatable by the opening/closing mechanism (not illustrated).

As illustrated in FIGS. 1 to 3, the guide 122 is a plate erected on the upper surface of the base 121. The guide 122 has an inclined surface that becomes higher toward the outer periphery of the rotary table 11. The pin 123 is a cylinder provided at a position that is eccentric from the axis of the base 121 and corresponds to the top of the guide 122. The pin 123 increases in diameter upward, so that an outer peripheral surface thereof forms an inverse tapered surface.

The pin 123 moves between the open position and the closed position according to the rotation of the base 121. In the closed position illustrated in FIG. 4B, the pin 123 holds the substrate W by coming into contact with the outer peripheral edge of the substrate W. In the open position illustrated in FIG. 4A, the pin 123 releases the substrate W by moving away from the substrate W. In the present embodiment, six pins 123 are synchronously brought into contact with the substrate W, thereby holding the substrate W such that the center of the substrate W is aligned with the axis of the rotary table 11.

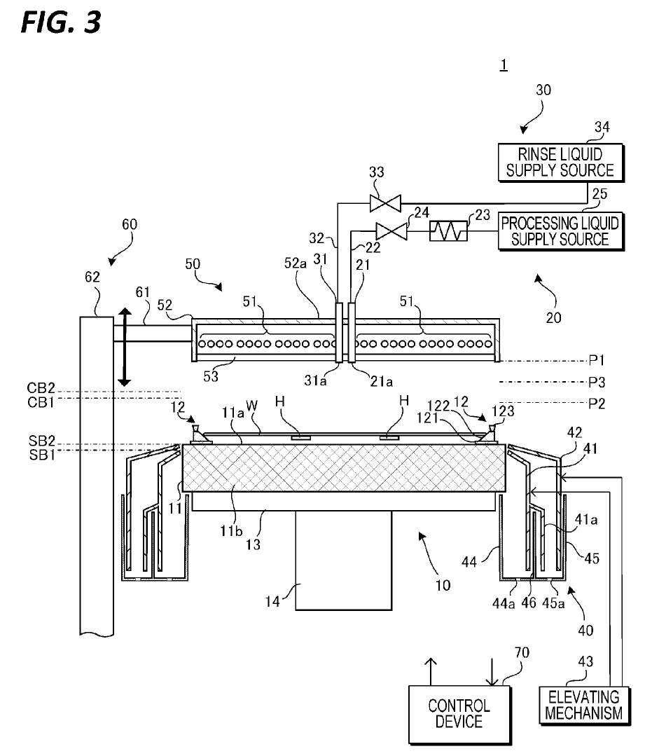

Further, with the pin 123 in the open position, the substrate W is disposed on the inclined surface of the guide 122 (see, e.g., FIGS. 3 and 4A). Then, as the base 121 rotates, the substrate W is raised by the inclined surface of the guide 122 that moves with the base 121, and the outer peripheral edge of the substrate W is held by the pin 123 that has moved to the closed position (see, e.g., FIG. 4B).

### Accommodation Unit

The accommodation unit 13 accommodates the opening/closing mechanism of the holding member 12. The accommodation unit 13 is a cylindrical member. The accommodation unit 13 is provided below the rotary table 11, and accommodates the opening/closing mechanism of the holding member 12.

### Driving Unit

The driving unit 14 is a drive source (e.g., a motor) that rotates the rotary table 11. The driving unit 14 rotates the substrate W held by the pin 123 by rotating the rotary table 11.

### Processing Liquid Supply Unit

As illustrated in FIG. 1, the processing liquid supply unit 20 supplies the processing liquid Lp to a surface of the rotating substrate W opposite to the opposing surface 11a. That is, the processing liquid supply unit 20 processes the substrate W by supplying the processing liquid Lp to an upper surface (e.g., a processing target surface) of the substrate W, which is held by the holding member 12 and is rotated by the rotary table 11. The processing liquid supply unit 20 includes a processing liquid nozzle 21, a processing liquid supply pipe 22, a heater 23, and a valve 24.

The processing liquid nozzle 21 is inserted through a support unit 52 and a transmission window 53 of the heating unit 50 to be described herein later, and is provided such that a discharge port 21a at the tip thereof faces the vicinity of the center of the substrate W held by the rotary holding unit 10.

The processing liquid nozzle 21 is connected, via the processing liquid supply pipe 22, to a processing liquid supply source 25 such as a tank in which the processing liquid Lp is stored. In the present embodiment, the processing liquid Lp delivered from the processing liquid supply source 25 is heated in advance. The heater 23 is provided in the middle of the processing liquid supply pipe 22. After the processing liquid Lp delivered from the processing liquid supply source 25 passes through the processing liquid supply pipe 22 and is heated by the heater 23, the processing liquid Lp is discharged from the discharge port 21a of the processing liquid nozzle 21 to the vicinity of the center of the substrate W.

The temperature of the processing liquid Lp discharged from the processing liquid nozzle 21 is, for example, 160 °C. Furthermore, the valve 24 is provided in the middle of the processing liquid supply pipe 22. By opening and closing the valve 24, the discharge of the processing liquid Lp from the processing liquid nozzle 21 is started and stopped. The valve 24 is electrically connected to the control device 70 to be described herein later, and the opening and closing of the valve 24 are controlled by the control device 70.

### Rinse Liquid Supply

As illustrated in FIG. 2, the rinse liquid supply unit 30 supplies the rinse liquid Lc to the surface of the rotating substrate W opposite to the opposing surface 11a. That is, the rinse liquid supply unit 30 cleans the substrate W by supplying the rinse liquid Lc to the upper surface of the substrate W, which is held by the holding member 12 and is rotated by the rotary table 11. For example, pure water may be used as the rinse liquid Lc.

The rinse liquid supply unit 30 includes a rinse liquid nozzle 31, a rinse liquid supply pipe 32, and a valve 33. The rinse liquid nozzle 31 is inserted through the support unit 52 and the transmission window 53 of the heating unit 50 to be described herein later, and is provided such that a discharge port 31a at the tip thereof faces the vicinity of the center of the substrate W held by the rotary holding unit 10.

The rinse liquid nozzle 31 is connected, via the rinse liquid supply pipe 32, to a rinse liquid supply source 34 such as a tank in which the rinse liquid Lc is stored. The rinse liquid Lc delivered from the rinse liquid supply source 34 passes through the rinse liquid supply pipe 32 and is discharged from the discharge port 31a of the rinse liquid nozzle 31 toward the vicinity of the center of the substrate W. The valve 33 is provided in the middle of the rinse liquid supply pipe 32. By opening and closing the valve 33, the discharge of the rinse liquid Lc from the rinse liquid nozzle 31 is started and stopped. The valve 33 is electrically connected to the control device 70 to be described herein later, and the opening and closing of the valve 33 are controlled by the control device 70.

### Liquid Receiving Unit

As illustrated in FIG. 1, the collecting unit 40 is provided to surround the rotary holding unit 10, and receives the processing liquid Lp and the rinse liquid Lc scattered from the rotating substrate W. The collecting unit 40 discharges the received processing liquid Lp and rinse liquid Lc out of the substrate processing apparatus 1.

The collecting unit 40 includes a first cup 41, a second cup 42, an elevating mechanism 43, a first liquid receiving unit 44, and a second liquid receiving unit 45. The first cup 41 and the second cup 42 cover the outer periphery of the rotating substrate W with a gap from the substrate W and the rotary table 11. The first cup 41 and the second cup 42 are cylindrical bodies that are bent such that an upper diameter thereof is reduced. The first cup 41 has a smaller diameter than the second cup 42, and is disposed inside the second cup 42.

The first cup 41 includes a skirt portion 41a formed on a side surface thereof facing the second cup 42. The skirt portion 41a is a cylindrical body that is bent such that an upper diameter thereof is reduced, and has an upper end fixed to the side surface of the first cup 41. By the skirt portion 41a, an annular space having a closed upper side and an open lower side is formed at a lower portion of the first cup 41.

The first cup 41 is provided to be movable between a standby position SB1 and a cover position CB1. The standby position SB1 is a lowered position at which loading and unloading of the substrate W are possible (see, e.g., FIG. 3). The standby position SB1 is equal to or lower than a height position of the opposing surface 11a of the rotary table 11. The cover position CB1 is a raised position at which the first cup 41 receives the processing liquid Lp scattered from the substrate W (see, e.g., FIG. 1). Since light is emitted from the heating unit 50 during processing of the substrate W with the processing liquid Lp, the first cup 41 is at the cover position CB1 during light irradiation by the heating unit 50. At the cover position CB1, an upper end of an inner wall of the first cup 41 is at a height equal to or higher than a position at which the heating unit 50 emits light. That is, the height of the upper end of the inner wall of the first cup 41 is equal to or higher than a height of a bottom surface of the transmission window 53 of the heating unit 50.

The second cup 42 is provided to be movable between a standby position SB2 and a cover position CB2. The standby position SB2 is a lowered position at which loading and unloading of the substrate W are possible (see, e.g., FIG. 3). The cover position CB2 is a raised position at which the second cup 42 receives the rinse liquid Lc scattered from the substrate W (see, e.g., FIG. 2), or a raised position when the first cup 41 is at the cover position CB1 (see, e.g., FIG. 1).

The elevating mechanism 43 is a mechanism that individually raises and lowers the first cup 41 and the second cup 42. Various mechanisms capable of moving the first cup 41 and the second cup 42 in a direction parallel to the axis of the rotary table 11, such as a cylinder or a ball screw mechanism, may be applied as the elevating mechanism 43, and a detailed description thereof will be omitted. In addition, the elevating mechanism 43 may be provided separately for each of the first cup 41 and the second cup 42.

The first cup 41 moves to the cover position CB1 when processing with the processing liquid Lp is performed, and moves to the standby position SB1 when rinsing with the rinse liquid Lc is performed and when the substrate W is loaded and unloaded. The second cup 42 moves to the cover position CB2 when rinsing with the rinse liquid Lc is performed and when processing with the processing liquid Lp is performed, and moves to the standby position SB2 when the substrate W is loaded and unloaded.

The first liquid receiving unit 44 is an annular container that is provided below the first cup 41 and has an open upper portion. The second liquid receiving unit 45 is an annular container that is provided below the second cup 42 and has an open upper portion. The first liquid receiving unit 44 and the second liquid receiving unit 45 are configured such that the inside of the annular container is partitioned into an inner side and an outer side by a cylindrical partition wall 46. The first liquid receiving unit 44 receives the processing liquid Lp that falls downward from the first cup 41. The second liquid receiving unit 45 receives the rinse liquid Lc that falls downward from the second cup 42.

The partition wall 46 is interposed without contact between a sidewall of the first cup 41 and an inner wall of the skirt portion 41a, thereby forming a labyrinth structure having a bent path, which makes it difficult for the processing liquid Lp to enter the second liquid receiving unit 45. Drain ports 44a and 45a are formed in bottom portions of the first liquid receiving unit 44 and the second liquid receiving unit 45, respectively. The drain port 44a is connected to a collection path for the processing liquid Lp via a drain pipe (not illustrated) for discharging the processing liquid Lp. The drain port 45a is connected to a collection path for the rinse liquid Lc via a drain pipe (not illustrated) for discharging the rinse liquid Lc.

### Heating Unit

As illustrated in FIG. 1, the heating unit 50 emits heating light from above the surface of the substrate W to which the processing liquid Lp is supplied. That is, the heating unit 50 heats the substrate W by emitting light from the light source onto the substrate W that is held and rotated by the rotary holding unit 10.

The processing liquid Lp supplied to the vicinity of the center of the substrate W flows to spread toward the outer peripheral edge of the substrate W by a centrifugal force. At this time, when there is no additional heating, the supplied high-temperature (160 °C) processing liquid Lp decreases in temperature as it flows on the substrate W, due to heat conduction to the substrate W and heat dissipation. Therefore, by heating the substrate W, the processing liquid Lp on the substrate W may be heated by heat conduction from the substrate W, so that the processing liquid Lp on the substrate W may be maintained at a high temperature. In addition, the output of the heating unit 50 may be controlled such that the temperature of the processing liquid Lp is not only maintained but also is further increased on the substrate W.

A light emitting element 51 is used as the light source. The light emitting element 51 emits light (e.g., electromagnetic waves) having a wavelength that is absorbed by the substrate W thereby heating the substrate W. Further, the light emitted from the light emitting element 51 has a wavelength that is transmitted through the processing liquid Lp. Here, the description "absorbed by the substrate W" means that the light incident on the substrate W is absorbed to an extent sufficient to heat the substrate W, and includes not only complete absorption by the substrate W but also cases where a part of the light is reflected by or transmitted through the substrate W. The description "transmitted through the processing liquid Lp" means that the light incident on the processing liquid Lp is transmitted through the processing liquid Lp to an extent sufficient to heat the substrate W, and also includes cases where a part of the light is absorbed or reflected by the processing liquid Lp.

For example, an LED that emits heating light is used as the light emitting element 51. The wavelength of the light emitted from the LED is, for example, 350 nm to 1,060 nm (e.g., 350 nm or more and 1,060 nm or less). According to an embodiment, the center wavelength may be 395 nm to 940 nm (e.g., 395 nm or more and 940 nm or less). In the present embodiment, an LED that emits light having a center wavelength of 395 nm is used. In addition, the output of the light emitting element 51 is controlled by the control device 70 to be described herein later.

Accordingly, even when the light from the light emitting element 51 is irradiated from above the space in which the substrate W is maintained, that is, from above the processing liquid Lp supplied to the substrate W, the light is transmitted through the processing liquid Lp, and is absorbed by the substrate W, so that the substrate W may be heated. Then, as the temperature of the processing liquid Lp increases due to the heat conduction from the substrate W, an etching rate (e.g., a processing rate) increases.

As described above, in the present embodiment, the entirety of the opposing surface 11a and the side surface 11b of the rotary table 11 and the entirety of the holding members 12 have a light absorption rate of 90 % or higher for the light from the heating unit 50. Therefore, the light from the heating unit 50 is suppressed from being reflected by a structure that is not blocked by the substrate W. As a result, heating of the substrate W by reflected light is reduced.

The heating unit 50 includes the support unit 52 and the transmission window 53, in addition to the above-described light emitting element 51. The support unit 52 is a member that supports a plurality of light emitting elements 51. The support unit 52 is a cylindrical member having an upper end closed by an upper plate 52a. A diameter of the support unit 52 is equal to or larger than a diameter of the substrate W. The support unit 52 is disposed above the rotary table 11 at a position facing the opposing surface 11a with a gap therebetween. Thus, the heating unit 50 is provided to emit light from the light emitting element 51 from above the space in which the substrate W is held by the rotary holding unit 10.

The transmission window 53 is a disk-shaped member that covers an end of the support unit 52 facing the rotary table 11. The transmission window 53 is made of a material that is resistant to the processing liquid Lp and transmits the light emitted from the light emitting element 51. For example, the transmission window 53 is made of quartz glass.

The transmission window 53 has a size equal to or larger than that of the substrate W. That is, the transmission window 53 has a diameter equal to or larger than a diameter of the substrate W. Further, in the present embodiment, the transmission window 53 has a diameter smaller than that of the opposing surface 11a of the rotary table 11, thereby preventing light irradiation onto a structure other than the substrate W. The light from the light emitting element 51 is emitted to the substrate W through the transmission window 53. As described above, while the light is being emitted by the heating unit 50, the height of the upper end of the inner wall of the first cup 41 is equal to or higher than a height position at which the heating unit 50 emits the light. That is, the height of the upper end of the inner wall of the first cup 41 at the cover position CB1 is higher than a height of the bottom surface of the transmission window 53.

As illustrated in FIG. 1, two through holes are formed in the vicinity of the center of the upper plate 52a of the support unit 52, and the transmission window 53 is provided with through holes at respective positions opposite to the through holes of the upper plate 52a. The processing liquid nozzle 21 and the rinse liquid nozzle 31 are respectively inserted through two pairs of these opposing through holes of the upper plate 52a and the transmission window 53, and the discharge ports 21a and 31a at the tips thereof are exposed from the transmission window 53 and face the substrate W.

The plurality of light emitting elements 51 are attached to the support unit 52 to face the rotary table 11 with the transmission window 53 interposed therebetween. The heating unit 50 has a plurality of regions in which the light emitting elements 51 are arranged. That is, the plurality of light emitting elements 51 are arranged separately in the plurality of regions. In the present embodiment, the light emitting elements 51 are provided in regions corresponding to different radial positions of the substrate W, and the output of the light emitting elements 51 may be controlled for each region. Further, the plurality of light emitting elements 51 are arranged such that the entire processing target surface of the substrate W may be irradiated with light.

### Elevating Mechanism

The elevating mechanism 60 supports the heating unit 50 and raises and lowers the heating unit 50, as illustrated in FIG. 1. The elevating mechanism 60 includes an arm 61 and a column 62. The arm 61 is a member extending in a direction parallel to the substrate W, and an outer peripheral portion of the support unit 52 is connected to one end of the arm 61. The column 62 is erected in a direction perpendicular to the substrate W, and supports the other end of the arm 61. The column 62 is provided to be movable upward and downward by a drive source (not illustrated) such as a ball screw mechanism or a cylinder.

The heating unit 50 is positioned at any one height of a loading/unloading position P1, a heating position P2, and a rinse position P3 by driving of the elevating mechanism 60. These positions are as follows:

Loading/unloading position P1: a height position spaced upward apart from the rotary table 11 such that a hand H of a transfer robot may be inserted (see, e.g., FIG. 3);

Heating position P2: a height position that is closer to the substrate W than the loading/unloading position P1 (see, e.g., FIG. 1), and does not come into contact with the processing liquid Lp on the substrate W; and

Rinse position P3: a height position between the loading/unloading position P1 and the heating position P2 (see, e.g., FIG. 2).

### Control Device

The control device 70 controls each component of the substrate processing apparatus 1. The control device 70 includes a processor that executes programs, a memory that stores various types of information such as programs and operating conditions, and a drive circuit that drives each component, in order to implement various functions of the substrate processing apparatus 1. That is, the control device 70 controls, for example, the rotary holding unit 10, the processing liquid supply unit 20, the rinse liquid supply unit 30, the collecting unit 40, the heating unit 50, and the elevating mechanism 60.

More specifically, the control device 70 controls operations of, for example, the opening/closing mechanism of the rotary holding unit 10, the driving unit 14, the heater 23 and the valve 24 of the processing liquid supply unit 20, the valve 33 of the rinse liquid supply unit 30, the elevating mechanism 43 of the collecting unit 40, and the elevating mechanism 60.

### Operation

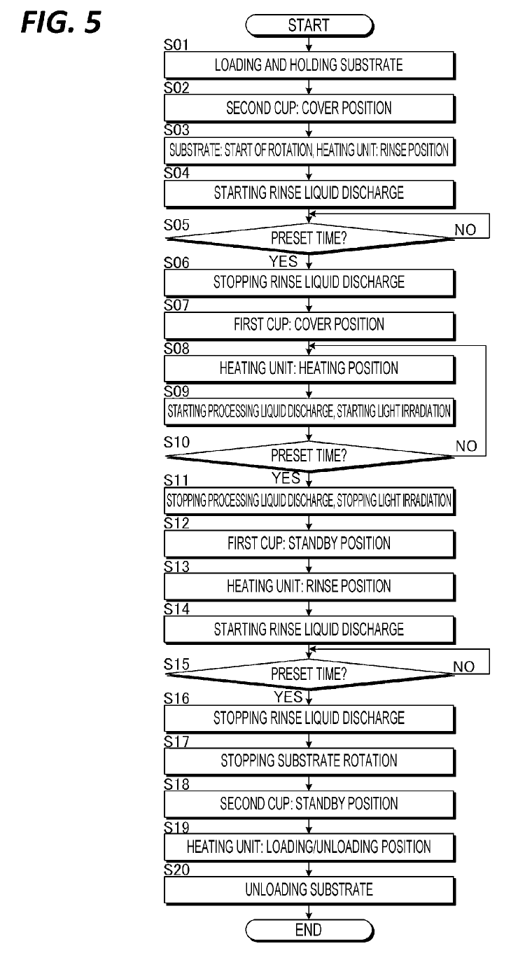

An operation of the substrate processing apparatus 1 according to the present embodiment described above will be described with reference to the flowchart of FIG. 5, in addition to FIGS. 1 to 4A and 4B. In addition, a substrate processing method of processing the substrate W by the following sequence is also an aspect of the present embodiment.

As illustrated in FIG. 3, the heating unit 50 is positioned in advance at the loading/unloading position P1, the first cup 41 is positioned at the standby position SB1, and the second cup 42 is positioned at the standby position SB2. The valve 24 of the processing liquid supply unit 20 and the valve 33 of the rinse liquid supply unit 30 are closed.

In this state, after the pin 123 is set to the open position, and the substrate W held by the hand H of the transfer robot is loaded between the heating unit 50 and the rotary table 11, the pin 123 is moved to the closed position, so that the outer peripheral edge of the substrate W is supported by the pin 123 (see, e.g., FIG. 4B). Thus, the substrate W is held on the opposing surface 11a of the rotary table 11 with a gap from the opposing surface 11a (step S01). At this time, the substrate W is positioned such that the center of the substrate W coincides with the rotation axis of the rotary table 11. Thereafter, as illustrated in FIG. 2, the second cup 42 is raised and positioned at the cover position CB2 (step S02).

Next, as the rotary table 11 rotates, the substrate W held by the pin 123 starts to rotate, and the heating unit 50 is lowered and positioned at the rinse position P3 (step S03).

Then, the valve 33 of the rinse liquid supply unit 30 is opened, and the rinse liquid Lc is discharged from the rinse liquid nozzle 31 toward the vicinity of the center of the substrate W (step S04). When the rinse liquid Lc is supplied to the rotating substrate W, the rinse liquid Lc sequentially moves toward the outer periphery of the substrate W and spreads over the entire processing target surface of the substrate W. The rinse liquid Lc scattered outward from the substrate W collides with the inner wall of the second cup 42 and falls downward into the second liquid receiving unit 45. Then, the rinse liquid Lc is discharged from the drain port 45a formed in the second liquid receiving unit 45.

When such supply of the rinse liquid Lc is not performed, when the processing liquid Lp is supplied, the processing liquid Lp does not wet and spread over the entire processing target surface of the substrate W due to surface tension, resulting in processing non-uniformity. In the present embodiment, in order to prevent such processing non-uniformity, the rinse liquid Lc is supplied in this step prior to supplying the processing liquid Lp. When a preset rinse time has elapsed (YES in step S05), the valve 33 of the rinse liquid supply unit 30 is closed, so that the discharge of the rinse liquid Lc from the rinse liquid nozzle 31 is stopped (step S06).

Next, as illustrated in FIG. 1, the first cup 41 is raised and positioned at the cover position CB1 (step S07), and the heating unit 50 starts to be lowered and stops upon reaching the heating position P2 (step S08). Then, the valve 24 of the processing liquid supply unit 20 is opened to discharge the processing liquid Lp from the processing liquid nozzle 21 toward the vicinity of the center of the substrate W, and heating of the substrate W by light irradiation by the light emitting elements 51 is started (step S09).

When the processing liquid Lp is supplied to the rotating substrate W, the processing liquid Lp sequentially moves toward the outer periphery of the substrate W and spreads over the entire processing target surface of the substrate W, so that processing by the processing liquid Lp proceeds. The processing liquid Lp scattered outward from the substrate W collides with the inner wall of the first cup 41 and falls downward into the first liquid receiving unit 44. Then, the processing liquid Lp is discharged from the drain port 44a formed in the first liquid receiving unit 44.

Since the rinse liquid Lc has been supplied in advance to the processing target surface of the substrate W, the processing liquid Lp wets and spreads over the entire processing target surface of the substrate W, so that processing non-uniformity is suppressed. Further, since the substrate W is heated by light from the heating unit 50, a decrease in the temperature of the processing liquid Lp on the substrate W is suppressed. However, since the reflection of light from the opposing surface 11a and the side surface 11b of the rotary table 11 and the reflection of light from the holding members 12 is suppressed, the heating of the substrate W due to reflected light is suppressed. Such processing using the processing liquid Lp is continued until a preset processing time elapses (NO in step S10).

When the preset processing time has elapsed (YES in step S10), the valve 24 of the processing liquid supply unit 20 is closed to stop the supply of the processing liquid Lp from the processing liquid nozzle 21, and the light irradiation by the light-emitting elements 51 is stopped (step S11).

As illustrated in FIG. 2, the first cup 41 is positioned at the standby position SB1 (step S12), and the heating unit 50 starts to be raised and stops upon reaching the rinse position P3 (step S13). Then, the valve 33 of the rinse liquid supply unit 30 is opened, and the rinse liquid Lc is discharged from the rinse liquid nozzle 31 toward the vicinity of the center of the substrate W (step S14). When the rinse liquid Lc is supplied to the rotating substrate W, the rinse liquid Lc sequentially moves toward the outer periphery of the substrate W and spreads over the entire processing target surface of the substrate W.

When the rinse liquid Lc is supplied to the processing liquid Lp, which is a phosphoric acid solution, a large amount of water vapor is generated. At this time, since the heating unit 50 is located at the rinse position P3, which is farther from the substrate W than the heating position P2, adhesion of water vapor to the heating unit 50 may be suppressed. Further, since the rinse position P3 is closer to the substrate W than the loading/unloading position P1, liquid splashing may be suppressed, thereby preventing adhesion of liquid droplets to the heating unit 50.

When a preset rinse time has elapsed (YES in step S15), the valve 33 of the rinse liquid supply unit 30 is closed, and the discharge of the rinse liquid Lc from the rinse liquid nozzle 31 is stopped (step S16). When the rotary table 11 stops, the substrate W held by the pin 123 stops rotating (step S17). Thereafter, the second cup 42 is lowered and positioned at the standby position SB2 (step S18).

As illustrated in FIG. 3, the heating unit 50 is raised and positioned at the loading/unloading position P1 (step S19). In this state, the hand H of the transfer robot is inserted below the substrate W, and the pin 123 is set to the open position, so that the substrate W is disposed on the hand H of the transfer robot and is unloaded to the outside (step S20). At this time, the rinse liquid Lc remains on the substrate W.

### Effect

(1) The substrate processing apparatus 1 according to the present embodiment includes a rotary table 11 having an opposing surface 11a that faces a substrate W, held at an outer peripheral edge thereof by a holding member 12, with a gap therebetween and that has a diameter larger than that of the substrate W, the rotary table 11 configured to rotate the substrate W held by the holding member 12, a processing liquid supply unit 20 configured to supply a processing liquid Lp to a surface of the rotating substrate W opposite to the opposing surface 11a, and a heating unit 50 configured to emit heating light from above the surface of the substrate W to which the processing liquid Lp is supplied, and the opposing surface 11a has a light absorption rate of 90% or higher in at least a region that does not overlap the substrate W in a plan view

When the light emitted from the heating unit 50 is reflected from the rotary table 11, reflected light is generated. The generated reflected light is blocked by the holding member 12, so that the amount of light incident on a region near the holding member 12 is reduced, while the reflected light is incident on other regions. Therefore, the amount of incident light becomes non-uniform in the circumferential direction of the substrate W.

In the present embodiment, even when the light emitted from the heating unit 50 is incident on a region of the rotary table 11 that does not overlap the substrate W, the light is absorbed by the rotary table 11. Accordingly, reflection by the rotary table 11 and incidence of reflected light onto the back surface of the substrate W may be suppressed. Accordingly, differences in the amount of incident light in the circumferential direction of an outer peripheral region within the plane of the substrate W are reduced, and temperature uniformity is improved, so that the uniformity of the processing rate in the circumferential direction may be enhanced.

In the present embodiment, the entirety of the opposing surface 11a of the rotary table 11 has a light absorption rate of 90 % or higher. Therefore, reflection may be reliably suppressed, and the manufacture and processing of the rotary table 11 are facilitated since the entirety of the opposing surface is made of a common material.

(2) The holding member 12 has a light absorption rate of 90 % or higher. Therefore, reflection of light by the holding member 12 may be suppressed, and therefore, differences in local light amount caused by light reflected by the holding member 12 and incident on the substrate W may be reduced. Accordingly, differences in the amount of incident light in the circumferential direction of an outer peripheral region within the plane of the substrate W are reduced, and temperature uniformity is improved, so that the uniformity of the processing rate in the circumferential direction may be enhanced. In particular, in the present embodiment, the holding member 12 includes the base 121 having an upper surface facing the substrate W. Since this base 121 also has a light absorption rate of 90 % or higher, light incidence to the back surface of the substrate W may be more reliably suppressed.

(3) The heating unit 50 includes a transmission window 53 having a size equal to or larger than that of the substrate W, and emits light onto the substrate W through the transmission window 53. Therefore, the entire surface of the substrate W may be irradiated and heated with light while suppressing reflection of light from a region of the rotary table 11 that does not overlap the substrate W.

(4) A portion having a light absorption rate of 90 % or higher is black. In this way, the light absorption rate may be readily set to 90 % or higher by forming such a portion of a black material.

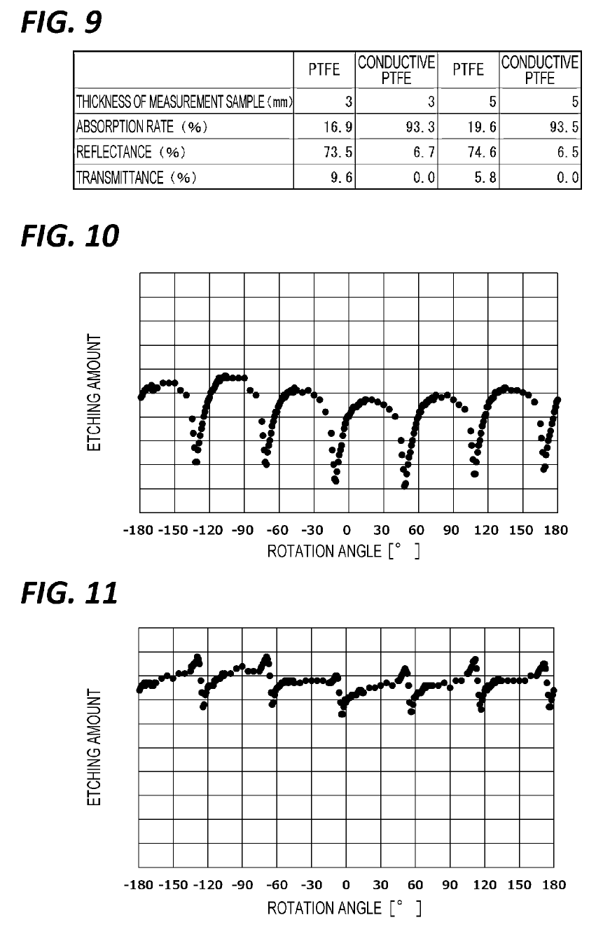

(5) The black portion is conductive PTFE. Therefore, it is possible to achieve a light absorption rate of 90 % or higher while ensuring resistance to the processing liquid Lp. FIG. 9 illustrates a table of the optical characteristics of general PTFE (white) and conductive PTFE (black). The values illustrated in FIG. 9 are the values of absorption rate, reflectance, and transmittance of each sample with respect to a wavelength of 395 nm. The reflectance and transmittance were measured using a UV-VIS-NIR spectrophotometer (PerkinElmer Lambda 950). The absorption rate was calculated as (100-(reflectance+transmittance)). As illustrated in FIG. 9, as compared with PTFE, conductive PTFE has a higher absorption rate and a lower reflectance. Therefore, reflection may be sufficiently suppressed by using conductive PTFE as in the present embodiment.

An example in which the etching amount in an outer peripheral region of the substrate W was measured over one circumference (360°) is illustrated in the graphs of FIGS. 10 and 11. FIG. 10 illustrates a case where the rotary table 11 is made of white PTFE, and FIG. 11 illustrates a case where the rotary table 11 is made of black conductive PTFE. In FIGS. 10 and 11, the horizontal axis represents the circumferential position (rotation angle), and the vertical axis represents the etching amount. Since the scales of the vertical and horizontal axes are the same in FIGS. 10 and 11, the magnitude of differences in etching amount may be compared. In FIGS. 10 and 11, a decrease in etching amount is observed with a cycle of 60°. The positions at which the etching amount is reduced correspond to the locations in which the six holding members 12 are provided. As can be seen from FIGS. 10 and 11, the rotary table 11 made of conductive PTFE may suppress the light reflection, and therefore, may exhibit smaller differences between locations having a larger etching amount and locations having a smaller etching amount in the circumferential direction, as compared with the rotary table 11 made of PTFE.

(6) The heating unit 50 includes a plurality of LEDs as the light emitting elements 51. Therefore, the entire substrate W may be uniformly heated by the plurality of LEDs, while light tends to be emitted onto a region that does not overlap the substrate W, but reflection may be suppressed since the light absorption rate of this region is 90 % or higher.

### Second Embodiment

### Configuration

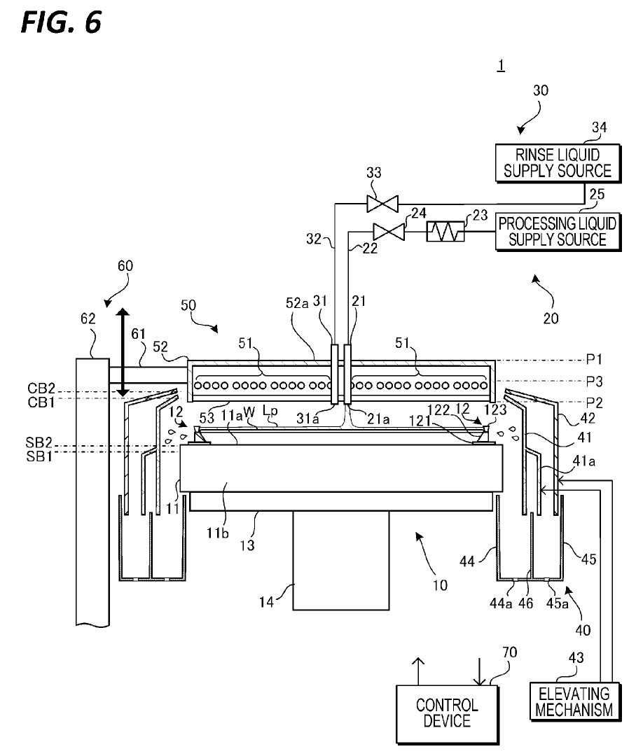

A second embodiment will be described with reference to FIG. 6. The present embodiment has substantially the same configuration as that of the first embodiment, and operates in the same manner, and therefore, descriptions of common matters will be omitted. However, in the present embodiment, at least the inner wall of the first cup 41 has a light absorption rate of 90 % or higher with respect to the light emitted by the heating unit 50.

In the present embodiment, the entirety of the first cup 41 has a light absorption rate of 90 % or higher. The first cup 41 is made of a black material. For example, the light absorption rate is set to 90 % or higher by forming the first cup 41 in black using a material containing carbon. More specifically, the conductive PTFE containing carbon is used in the first cup 41. Alternatively, a member made of a black material may be assembled to the inner wall of the first cup 41, or a black material may be applied thereto. In addition, in the present embodiment, the opposing surface 11a may not be configured to reduce light reflection.

### Operation

The operation of the present embodiment is the same as that of the first embodiment described above along with steps S01 to S20. However, in step S09, when the processing liquid Lp is discharged from the processing liquid nozzle 21 to the vicinity of the center of the substrate W and heating of the substrate W by emission of light from the light emitting elements 51 is started, heating of the substrate W by reflected light is suppressed since light reflection by the first cup 41 located at the cover position CB1 is suppressed.

### Effect

The substrate processing apparatus 1 of the present embodiment includes a rotary holding unit 10 that rotates a substrate W held by a holding member 12, a processing liquid supply unit 20 that supplies a processing liquid Lp to an upper surface of the rotating substrate W, a heating unit 50 that emits heating light from above the upper surface of the substrate W, and a cup (e.g., the first cup 41) that covers an outer periphery of the rotating substrate W with a gap from the substrate W, wherein at least an inner wall of the first cup 41 has a light absorption rate of 90 % or higher.

When the light emitted from the heating unit 50 is reflected by the first cup 41, reflected light is generated. The generated reflected light is blocked by the holding member 12, so that the amount of light incident on a region near the holding member 12 is reduced. Therefore, the amount of incident light becomes non-uniform in the circumferential direction of the substrate W.

In the present embodiment, while heating is performed during supply of the processing liquid Lp, reflection of light from the first cup 41 may be suppressed since the inner wall of the first cup 41 surrounding the substrate W is made of a material having a high light absorption rate. Accordingly, light that is reflected by the first cup 41 and then incident on the substrate W is reduced, and differences in the amount of incident light in the circumferential direction of an outer peripheral region within the plane of the substrate W are reduced, and temperature uniformity is improved, so the uniformity of the processing rate in the circumferential direction may be enhanced.

In addition, as in the first embodiment described above, while light is being emitted by the heating unit 50, the height of the upper end of the inner wall of the first cup 41 is equal to or higher than a position at which the heating unit 50 emits light, so that the processing liquid Lp may be efficiently collected.

### Third Embodiment

### Configuration

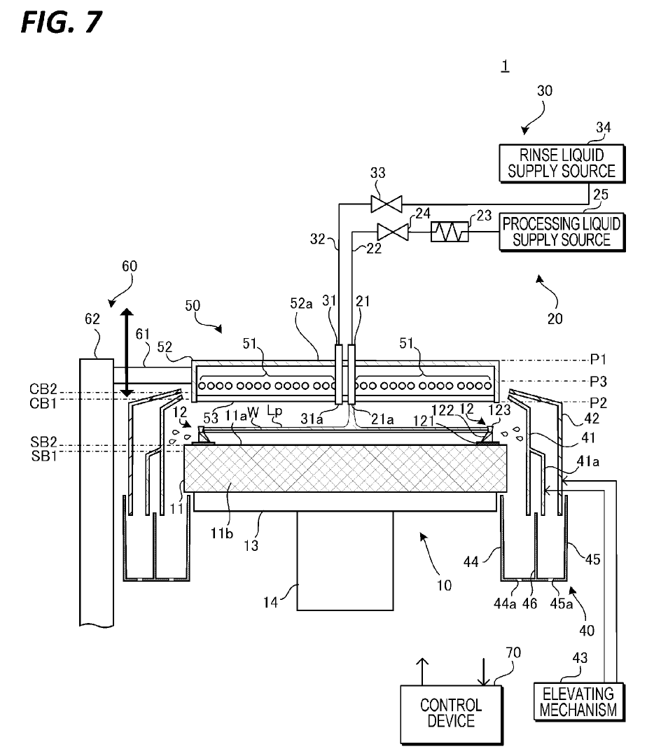

A third embodiment will be described with reference to FIG. 7. The third embodiment substantially has the same configuration as those of the first embodiment and the second embodiment, and operates in the same manner. That is, as in the first embodiment, the opposing surface 11a and the side surface 11b of the rotary table 11, and the holding member 12 have a light absorption rate of 90 % or higher. In addition, as in the second embodiment, the first cup 41 of the present embodiment has a light absorption rate of 90 % or higher. Descriptions of other matters common to the first and second embodiments will be omitted.

### Operation

The operation of the present embodiment is the same as that of the first embodiment described above along with steps S01 to S20. However, in step S09, when the processing liquid Lp is discharged from the processing liquid nozzle 21 to the vicinity of the center of the substrate W and heating of the substrate W by emission of light from the light emitting elements 51 is started, irradiation of the substrate W with reflected light is reduced since light reflection from the opposing surface 11a of the rotary table 11, the holding member 12, and the first cup 41 is suppressed.

### Effect

In the substrate processing apparatus 1 of the present embodiment, at least a region of the opposing surface 11a of the rotary table 11 that does not overlap the substrate W in a plan view has a light absorption rate of 90 % or higher, and at least the inner wall of the first cup 41 has a light absorption rate of 90 % or higher. Further, the holding member 12 has a light absorption rate of 90 % or higher.

In the present embodiment, while heating is performed during supply of the processing liquid Lp, the reflection of light from the opposing surface 11a, the holding member 12, and the first cup 41 is suppressed. Accordingly, since light that is reflected and then incident on the substrate W is further reduced, temperature uniformity in the circumferential direction is improved, so that the uniformity of the processing rate in the circumferential direction may be enhanced.

### Modification

(1) In the first embodiment and the third embodiment, the entirety of the opposing surface 11a may not have a light absorption rate of 90 % or higher. It is sufficient that at least a region that does not overlap the substrate W in a plan view has a light absorption rate of 90 % or higher.

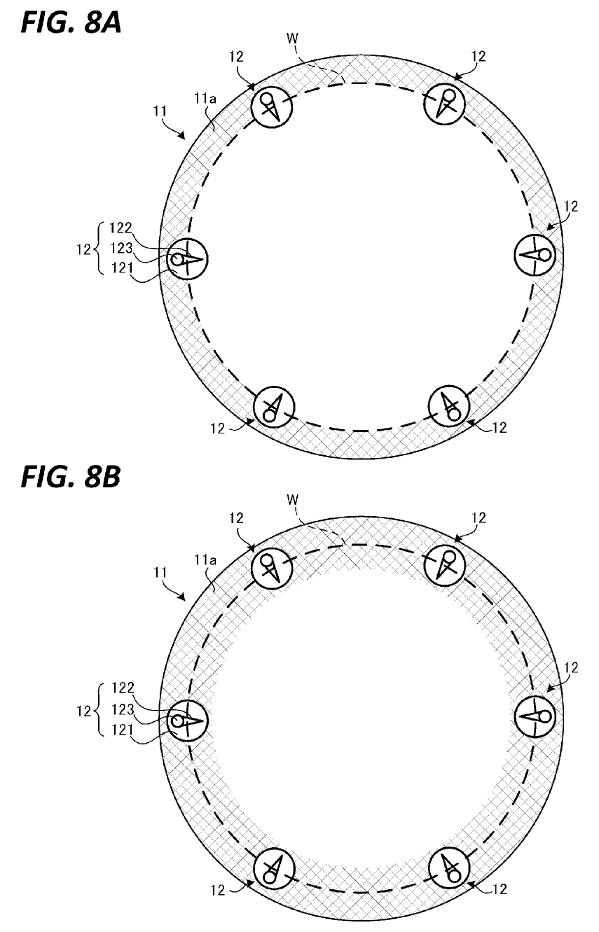

For example, as illustrated in FIG. 8A, a ring-shaped region (e.g., the region indicated by cross hatching) that does not overlap the substrate W in a plan view may have a light absorption rate of 90 % or higher. Such an opposing surface 11a may be formed, for example, by fitting a ring-shaped black member or applying a black material. Since the ring-shaped region is heated by absorbing light, the effect of heating the outer peripheral region of the substrate W may be obtained.

In addition, as illustrated in FIG. 8B, the ring-shaped region may extend to a region overlapping the substrate W in a plan view. Such a ring-shaped region may more reliably suppress light reflection by overlapping the substrate W.

(2) The light source of the heating unit 50 is not limited to LEDs. Any light source may be used as along as it may heat a heating target with light. For example, a halogen lamp or a flash lamp may be used. However, arranging a plurality of LEDs makes it possible to heat the substrate W more uniformly.

(3) The color of a region capable of reducing light reflection is not limited to black. It is sufficient that the absorption rate of light from the heating unit 50 is 90 % or higher.

(4) In order to set the light absorption rates of the rotary table 11, the holding member 12, and the first cup 41 to 90 % or higher, in addition to forming them using materials having a light absorption rate of 90 % or higher, coating or attachment of other members may be performed as described above. That is, it is also possible to apply a material having such an absorption rate, to assemble a member having such an absorption rate, or to attach a sheet having such an absorption rate. In the case of the rotary table 11, a plate made of a material having such an absorption rate may be placed on the rotary table 11. In this case, an upper surface of the plate also serves as the opposing surface 11a. Further, in the case of the holding member 12, it is sufficient that a portion exposed from the opposing surface 11a of the rotary table 11 has such an absorption rate.

(5) The holding member 12 only needs to be capable of holding the outer peripheral edge of the substrate W, and is not limited to one using the eccentrically rotating pin 123. For example, it may be a hook-shaped member that rotates about a horizontal axis in a direction in which it is brought into contact with and is separated away from the outer peripheral edge of the substrate W. In addition, depending on aspects of the holding member 12, the opposing surface 11a may be smaller than the substrate W, or there may be no member that may be referred to as the rotary table 11 or the opposing surface 11a. In that case, it is sufficient that one or both of the holding member 12 and the first cup 41 have a region with a light absorption rate of 90 % or higher, as described above.

(6) The processing performed by the substrate processing apparatus 1 is not limited to an etching processing. Any apparatus may be used as long as it processes the substrate W while supplying the processing liquid Lp and heating the substrate W. For example, a resist removal processing for removing a resist film formed on the substrate W may be employed.

(7) The processing liquid Lp is not limited to a phosphoric acid solution. Any processing liquid Lp that requires heating may be used. For example, hydrofluoric acid may be used. Further, in the case of resist removal processing, a sulfuric acid-hydrogen peroxide aqueous solution (SPM) may be used as the processing liquid Lp.

(8) The substrate W as a processing target may be an Si substrate having a resist formed on a surface thereof. Furthermore, the substrate W is not limited to an Si substrate. For example, it may be an SiC substrate (e.g., silicon carbide wafer).

(9) For example, the number and the arrangement position of light emitting elements 51 are not limited to the embodiments described above. The light from the light source may be guided onto the substrate W via optical fibers and emitted therefrom. Therefore, the light emitting elements 51 may not be disposed above the substrate W.

(10) In the above-described embodiments, the rinse liquid nozzle 31 is configured to penetrate the support unit 52 and the transmission window 53, but a mechanism for moving the rinse liquid nozzle 31 in a horizontal direction may be provided to move the rinse liquid nozzle 31 to above the vicinity of the center of the substrate W when supplying the rinse liquid Lc.

(11) The support unit 52 on which the light emitting elements 51 are disposed has been described as a circular member having a diameter equal to or larger than the diameter of the substrate W, but the present disclosure is not limited thereto. Any configuration may be used as long as light may be emitted onto the entire surface of the rotating substrate W. For example, a rectangular member having a size capable of covering the radius of the substrate W may be used. When irradiation may be performed over the radius of the substrate W, the entire surface of the substrate W may be irradiated as the substrate W rotates. Further, the support unit 52 may be provided to be swingable in a horizontal direction, and irradiation over the entire surface of the substrate W may be achieved by swinging the support unit 52 while emitting light from the light emitting elements 51.

In this way, when the support unit 52 is smaller than the diameter of the substrate W, a mechanism for moving the processing liquid nozzle 21 in a horizontal direction may be provided to move the processing liquid nozzle 21 to above the substrate W during supply of the processing liquid. That is, the processing liquid nozzle 21 may be disposed at any position as long as it may supply the processing liquid Lp toward the vicinity of the center of the substrate W while light irradiation by the light emitting elements 51 is performed.

### Other Embodiments

The embodiments of the present disclosure and modifications of each component have been described above, but these embodiments and modifications are presented as examples and are not intended to limit the scope of the disclosure. These novel embodiments described above may be implemented in various other forms, and various omissions, substitutions, combinations, and changes may be made without departing from the spirit of the disclosure. These embodiments and modifications thereof are included in the scope and gist of the disclosure, and are also included in the disclosure described in the claims.

What is claimed is:

1. A substrate processing apparatus comprising:
a rotary table having an opposing surface that faces a substrate, held at an outer peripheral edge thereof by a holding member, with a gap therebetween and that has a diameter larger than that of the substrate, the rotary table configured to rotate the substrate held by the holding member;
a processing liquid supply configured to supply a processing liquid to a surface of the rotating substrate opposite to the opposing surface; and
a heater configured to emit heating light from above the surface of the substrate to which the processing liquid is supplied,
wherein the opposing surface has a light absorption rate of 90 % or higher in at least a region that does not overlap the substrate in a plan view.

2. The substrate processing apparatus according to claim 1, wherein the holder has a light absorption rate of 90 % or higher.

3. The substrate processing apparatus according to claim 1, further comprising:
a cup configured to cover an outer periphery of the rotating substrate with a gap from the substrate and the rotary table,
wherein at least an inner wall of the cup has a light absorption rate of 90 % or higher.

4. The substrate processing apparatus according to claim 3, wherein the holder has a light absorption rate of 90 % or higher.

5. A substrate processing apparatus comprising:
a rotary holder configured to rotate a substrate held by a holding member;
a processing liquid supply configured to supply a processing liquid to an upper surface of the substrate which is rotating;
a heater configured to emit heating light from above the upper surface of the substrate; and
a cup configured to cover an outer periphery of the substrate which is rotating with a gap from the substrate,
wherein at least an inner wall of the cup has a light absorption rate of 90 % or higher.

6. The substrate processing apparatus according to claim 5, wherein the holding member has a light absorption rate of 90 % or higher.

7. The substrate processing apparatus according claim 1, wherein a portion having a light absorption rate of 90 % or higher is made of a black material.

8. The substrate processing apparatus according to claim 7, wherein the black portion is conductive PTFE.

9. The substrate processing apparatus according to claim 3, wherein, when light is emitted by the heater, a height of an upper end of the inner wall of the cup is equal to or higher than a position at which the heater emits light.

10. The substrate processing apparatus according to claim 1, wherein the heater includes a transmission window having a size equal to or larger than that of the substrate, and emits light onto the substrate through the transmission window.

11. The substrate processing apparatus according to claim 1, wherein the heater includes a plurality of LEDs as a light source.
